(19) United States
(12) Patent Application Publication
(10) Pub. No.: US 2011/0152102 A1
(43) Pub. Date: Jun. 23, 2011

(54) DEVICE AND METHOD OF MEASURING ELECTRICAL DISSIPATION IN A SUPERCONDUCTING COIL

(76) Inventor: JOHN H CLAASSEN, Washington, DC (US)

(21) Appl. No.: 12/644,194

(22) Filed: Dec. 22, 2009

(51) Int. Cl. H01L 39/02; H01B 12/00; H01L 39/24; H02H 7/00; H01L 39/12

(52) U.S. Cl. 505/160; 505/230; 505/433; 361/19; 29/599

(57) ABSTRACT

An apparatus, system and method for measuring electrical dissipation in a coil wound with superconducting wire or tape are disclosed. The superconducting coil may include one or more superconducting wires wound together with a witness winding. The one or more superconducting wires may be electrically connected to the witness winding. The one or more superconducting wires may be shaped as a tape. The witness winding may be a tape. The superconducting coil may be wound into a flat pancake structure. The witness winding may be configured to detect a quench in the one or more superconducting wires, which may otherwise interfere with the superconductivity of the one or more superconducting wires.

### BACKGROUND

1. Field of the Invention

This invention relates to an apparatus, system and method for measuring electrical dissipation in a coil wound with superconducting wire or tape.

2. Description of the Related Art

An electrical inductor is capable of storing energy in the magnetic field produced by current flowing through the inductor coil. If the inductor is a superconducting inductor, resistance of the inductor winding approaches zero ohms enabling the winding to carry large currents with little loss. Thus, superconducting inductors can store extremely large amounts of energy for relatively long periods of time. Superconducting magnetic energy storage systems may be used in various fields such as industrial, transportation, and defense, as well as in the electrical utility industry.

### SUMMARY OF CERTAIN INVENTIVE ASPECTS

In one aspect, a superconducting coil includes a superconducting tape. The superconducting tape may include a superconducting metal material. The metal material may comprise bismuth strontium calcium copper oxide, yttrium barium copper oxide, thallium barium calcium copper oxide and/or mercury barium calcium copper oxide. In some embodiments, the superconducting coil also includes a witness tape. The witness tape may include a metal electrically connected to the superconducting tape. The superconducting tape and the witness tape may be wound into a superconducting coil formed in a flat pancake structure.

In another aspect, a system for detecting quenches in superconducting coil includes a superconducting coil having a plurality of turns and comprising a plurality of wires, wherein the superconducting coil is wound into a pancake coil, and wherein the superconducting coil is configured to carry an alternating current. The system further includes a witness wire interwoven in the superconducting coil with the plurality of wires, wherein the witness wire includes a tape. The system further includes a quench detector electronically connected to the witness wire and to the superconducting coil at one end.

In some embodiments, the superconducting coil comprises an inductor. In some embodiments, the superconducting coil comprises a winding in a transformer. In some embodiments, the quench detector further comprises an isolation amplifier. In some embodiments, the quench detector is configured to detect an increase in differential voltage. In some embodiments, the quench detector is configured to detect the increase in differential voltage along the entire length of the superconducting coil. In some embodiments, the plurality of wires includes copper wires. In some embodiments, the plurality of wires includes brass wires. In some embodiments, the plurality of wires may include bismuth strontium calcium copper oxide, yttrium barium copper oxide, thallium barium calcium copper oxide and/or mercury barium calcium copper oxide.

In some embodiments, the system is electrically connected to a power line transmission system. In some embodiments, the witness wire comprises a feature to distinguish it from the plurality of wires. In some embodiments, the feature is a color. In some embodiments, the feature is a texture.

In some embodiments, the superconducting wire is configured for high temperature superconducting. In some embodiments, the plurality of wires comprises a material with a transition temperature greater than about 77° K. In some embodiments, the plurality of wires comprises a material with a transition temperature between about 77° K and about 92° K. In some embodiments, the plurality of wires comprises a material with a transition temperature between about 92° K and about 110° K. In some embodiments, the plurality of wires comprises a material with a transition temperature between about 110° K and about 128° K. In some embodiments, the plurality of wires comprises a material with a transition temperature between about 128° K and about 135° K. In some embodiments, the plurality of wires comprises a material with a transition temperature greater than about 135° K.

In some embodiments, the witness wire comprises a metal coated plastic film. In some embodiments, the witness wire comprises part of an overall insulation between superconducting coil windings. In some embodiments, the witness wire comprises one or more round wires in parallel. In some embodiments, the witness wire comprises a resistance greater than 1000 ohms.

In another aspect, a method for making a high temperature superconductor tape with a witness tape in a flat pancake structure includes mixing high temperature superconductor materials to form a mixture; reacting the mixture of high temperature superconductor materials to form a powder; packing the powder into a plurality of billets; subjecting the plurality of billets to repeated drawing and swaging to produce a plurality of filaments; combining and deforming the plurality of filaments to form a high temperature superconducting tape; and winding the high temperature superconducting tape with a witness tape to form a high temperature superconductor coil in a flat pancake structure. In some embodiments, the high temperature superconductor materials may include, for example bismuth strontium calcium copper oxide, yttrium barium copper oxide, thallium barium calcium copper oxide and/or mercury barium calcium copper oxide.

In another embodiment, a utility system includes a utility configured to provide electric power to a load via a network; a superconducting inductor immersed in a cryogenic fluid, wherein the superconducting transformer winding comprises a superconducting coil wound with a witness tape in a flat pancake structure, and wherein the transformer winding is configured to receive electric power from the utility; and a quench detection and control circuit responsive to signals from the witness tape in the superconducting coil.

### BRIEF DESCRIPTION OF THE DRAWINGS

The foregoing and other features of the present disclosure will become more fully apparent from the following description and appended claims, taken in conjunction with the accompanying drawings. Understanding that these drawings depict only several embodiments in accordance with the disclosure and, therefore, are not to be considered limiting of its scope; the disclosure will be described with additional specificity and detail through use of the accompanying drawings. An apparatus, system or method according to the present disclosure can have several aspects, no single one of which necessarily is solely responsible for the desirable attributes of the apparatus, system or method. After considering this discussion, and particularly after reading the section entitled “Detailed Description of Certain Inventive Embodiments” one will understand how the features of this invention provide advantages that include the ability to make and use an apparatus, system or method for detecting electrical dissipation in a superconducting coil.

FIG. 1 illustrates a block diagram of a system for detecting a quench in a utility system application of a superconducting coil.

FIG. 2 illustrates one embodiment of a quench detection/control circuit.

FIG. 3 illustrates one embodiment of a superconducting coil.

FIG. 4 depicts a method of making a superconducting coil in a pancake structure.

### DETAILED DESCRIPTION OF CERTAIN INVENTIVE EMBODIMENTS

The illustrative embodiments described in the detailed description, drawings, and claims are not meant to be limiting. As will be appreciated, the following detailed description is directed to certain specific embodiments. Other embodiments may be utilized, and other changes may be made, without departing from the spirit or scope of the subject matter presented here. The technology described herein can be embodied in a multitude of different ways. It will be readily understood that aspects of the present disclosure, as generally described herein, and illustrated in the figures, can be arranged, substituted, combined, and designed in a wide variety of different configurations, all of which are explicitly contemplated and make part of this disclosure. It is to be understood that the disclosed embodiments are not limited to the examples described below, as other embodiments may fall within the present disclosure and the claims.

The technology described herein may be used, for example, in energy storage devices including inductors, or windings that form part of a transformer. Some types of inductors useful with the present technology include superconducting inductors. Superconducting inductors may be configured to store large amounts of energy for relatively long periods of time. One type of inductor winding may include strands of superconducting material, such as niobium-titanium. A transformer is a device that transfers electrical energy from one circuit to another through inductively coupled conductors, which may be referred to as coils or “windings”. Like inductors mentioned above, transformers may include superconducting windings.

Every superconducting material has a critical temperature above which the material is no longer superconducting. Thus, for example, when a superconducting inductor is in use, the entire superconducting inductor may be immersed in a cryogenic fluid, such as liquid helium, so the superconducting coil may maintain its superconductive state.

A “quench” is said to occur when a region of superconductor loses its superconducting property and becomes a normal resistive conductor. A quench may result in localized heating of the coil. The heating of the coil may cause the quench zone to propagate and lead to severe or catastrophic damage of the coil. More specifically, when a quench occurs a “hot spot” may develop and excess dissipation occurs. As the temperature increases the dissipation increases and the entire coil may be driven into a non-superconducting state within a relatively short period of time. This may result in damage to the coil. Some types of quench protection may involve an array of temperature sensors attached to the coil at various points.

Accordingly, a system may be provided for the early detection of quenches so that energy stored in the inductor may be dissipated in external resistors, thus preserving the integrity of the inductor so that corrective action may be taken. Some types of quench protection may involve an array of temperature sensors attached to the coil at various points. For example, voltage taps and voltage comparisons have been used for detecting and localizing incipient quench zones. These and other methods for quench detection may require either expensive state of the art amplifiers and/or time consuming fabrication techniques. Thus, some embodiments of the present disclosure allow for the quench detection to be accomplished with a significant economic savings. In some embodiments, superconducting coils are configured to allow rapid and accurate measurement of electrical dissipation occurring in a coil wound together with superconducting wire or tape.

In one aspect, a superconducting inductor may include both a superconducting coil and a second winding electrically isolated from the superconducting coil. A superconducting coil may include a superconducting wire or group of wires wound together with the second winding. The superconducting coil may have a plurality of turns and include a plurality of wires. The superconducting coil may be wound into a pancake coil configured to carry an alternating current. The second winding, or “witness winding” may include a non-superconducting metal. The wire or group of wires may comprise a tape. The tape structure may be interwoven in the superconducting coil with the plurality of wires. The one or more wires may comprise a wire with a round cross section. The witness winding may include a metal coated plastic film. The witness winding may include part of an overall insulation between tape windings. The witness winding may include a pair or wires, one along each edge of a tape. The witness winding may include a relatively large resistance since it carries no current. The large resistance may be, for example, thousands of ohms. The witness winding may occupy comparatively little extra volume with respect to the superconducting coil. In some embodiments, if the superconducting coil comprises a superconducting wire, a companion witness wire may include a comparatively smaller diameter wire simultaneously wound with the superconducting wire.

The witness winding is electrically connected at one end of a superconducting coil, but it otherwise insulated from the superconducting coil. In some embodiments, the witness winding encloses the same magnetic flux Φ as the superconducting coil. The overall voltage across either the superconducting coil or the witness winding is dominated by the rate of change of flux dΦ/dt. Faraday's law states the induced electromotive force (EMF) in any closed circuit is equal to the time rate of change of the magnetic flux dΦ/dt through the circuit. In addition, there is an additional voltage related to the dissipation in the wire. Under most circumstances dΦ/dt is much large than any voltage component due to losses in the superconductor and it would be difficult to extract the loss voltage from the total. In some embodiments, the voltage difference between the superconducting coil and the witness winding is due to dissipation in the superconductor winding, which under normal operation is relatively small. The voltage difference between the superconducting coil and the witness winding may be measured with an isolation amplifier. Isolation amplifiers may be configured to measure small differential voltages even when the total voltage is several kV. Thus, an increase in the differential voltage anywhere along the length of the superconducting coil may indicate development of a hot spot. Corrective action may then be taken to reduce power to the coil rapidly enough to prevent damage to the superconducting coil.

In one aspect, a system for detecting quenches in superconducting coil includes the superconducting coil, the witness wire and a quench detector. The quench detector may be electronically connected to the witness wire and to the superconducting coil.

In one aspect, methods of detection of a quench utilize the system including the superconducting coil, the witness wire and the quench detector described above. In some embodiments, methods of detection of a hot spot may be used to detect development of excess electrical dissipation within a few ac cycles. In some embodiments, a few ac cycles includes only tens of milliseconds at a line frequency. These methods may thus be per-formed much faster than is possible with thermal sensing, which relies on diffusion of heat from the hot spot to reach a thermometer or other heat sensing device. In some embodiments, methods of detection may only use a single measurement to monitor loss along all of a superconducting coil length, whereas with a temperature sensor multiple sensors would be required along the entire superconducting coil length. In some embodiments, methods of detection may measure intrinsic dissipation in the superconducting coil.

FIG. 1 illustrates a block diagram of a utility system 100 that uses a high temperature superconductor as described below. Although utility systems can include various types of organizations that provide goods or services consumed by the public, including, for example, electricity, natural gas, water, sewage, and/or telephone, utility system 100 is an illustrated system for providing electricity. The utility system 100 includes a superconducting coil in a utility 102 configured to provide electric power to a load 106 via a switching/combining network 104. As mentioned above, superconducting coils (magnets, inductors, solenoids etc.) described herein may be used in a variety of systems or energy storage devices such as inductors or windings that form part of a transformer.

The utility system 100A is also configured to detect a quench within a superconducting magnetic energy storage system (“SMES”). The SMES includes a superconducting transformer winding 108 immersed in a cryogenic fluid 110 within a cryostat. In addition to supplying energy during power outages, the SMES system may also be used for voltage and frequency control and for augmenting the utility supply.

The transformer winding 108 includes a witness tape 112 wound together with a superconducting coil portion. Charging current for the transformer winding 108 is supplied from the utility 102 via a first power conditioning circuit. Stored energy from the transformer winding 108 is returned to the utility grid via a second power conditioning circuit and switching/combining network 104. During charging of the transformer winding 108, a first switch may be open while other switches are closed. After the charging cycle all of the switches are closed so that the stored current traverses a loop which includes the transformer winding 108 and switches. For supplying current to the load 106 via power conditioning circuit and switching/combiner network 104, a first switch is closed, a second switch is open and other switches are closed.

A quench detection/control circuit 114 is electrically connected to and responsive to signals from the witness tape 112 wound together with the superconducting coil. The signals may indicate when and where a quench is occurring along a portion of the superconducting coil. The quench detection/control circuit 114 is also responsive to control signals on line from a central control and is responsive to certain transformer winding 108 voltage measurements to control operation of a plurality of switches. If the quench detection and control circuit 114 detects a quench, all of the stored energy must be dumped in order to protect the transformer winding 108. This is accomplished by closing the first and second switches while opening the other switches to direct previously stored current to a dump resistor and shunt the energy away from the quench region of the transformer winding 108.

For some applications the total voltage drop across the transformer winding 108 may reach thousands of volts, and accordingly the voltage between successive taps can approach a thousand volts or more. With no quench the two voltage inputs to each amplifier are separated by, for example, one thousand volts. For this condition the amplifier output does not exceed a predetermined threshold whereby the switches would be activated. With a quench situation, however, a loss of superconductivity at the quench location somewhere between two taps will cause a resistive voltage drop which may be in the order of only a few volts. The amplifiers therefore must be designed to be able to detect the presence of a few volts in perhaps a thousand volts.

To obviate the requirement for these high voltage isolation amplifiers, the transformer winding 108 includes the witness tape 112 (or other type of witness winding mentioned above). Between each tap is the respective witness tape 112, which may include any suitable non-superconducting material. In some embodiments, the witness tape 112 includes copper. As discussed above, the witness tape 112 may experience the same, inductive voltages as the superconducting transformer winding 108, but not the resistive quench voltage. Essentially equal inductive voltages are provided as inputs to respective amplifiers, which accordingly, may now be relatively inexpensive devices needing only to detect the presence of a resistive low voltage quench in the presence of a theoretically zero inductive voltage differential (instead of a thousand-volt differential).

Methods of incorporating the witness tape 112 may include, for example, wrapping of the transformer winding 108 with a normal copper conductor. Due to the presence of a coil form around which the cable is wound, interlayer insulators and reinforcing strapping it may be impractical to merely wrap the copper conductor around the cable without disrupting the coil structure. Another method of implementing the witness tape 112 may include, for example, providing an interlayer insulator with a groove formed such as by a milling operation, and into which the witness tape 112 may be placed.

Some conventional superconductive cables may be formed into a superconducting inductor and utilized in one or more of the systems described herein. The cable may be a flat cable comprised of a plurality of superconducting strands, transposed to balance current distribution. Each strand may include a plurality of superconducting filaments, such as niobium-titanium, embedded in a copper matrix and surrounded by a copper cladding. The superconducting cable, like the transformer winding 108 mentioned above, may include a witness winding, like the witness tape 112 described above, integral with the cable. For example, one superconducting strand, which normally is a part of the cable, is replaced with the witness winding which is of a non-superconducting material, such as copper, and which may include a jacket, of an electrically insulating material. This jacket may be of a contrasting color so that the witness winding may be easily distinguished from the other strands. The witness winding may then be cut at selected locations for electrical connection to the superconducting cable and to the amplifiers of the quench detection and control circuit. One type of superconducting cable integrated with witness winding is discussed further below with regard to FIG. 3.

FIG. 2 illustrates one embodiment of the quench detection/control circuit 114. Terminals 202A and 202B of the transformer winding 108 are connected to an external circuit providing an ac current excitation. In other embodiments, the transformer winding 108 could be incorporated, for example, as part of a rotating machine or inductor. The witness tape 112 is electrically connected to one end of the transformer winding 108 and is electrically insulated over its remaining length. Isolation amplifier 208 is electrically connected to terminal 202B and the witness tape 112 and configured to amplify a signal from the witness tape 112 to indicate a possible quench. Amplitude detector 210 is electrically connected to the isolation amplifier 208 and functions as an ac amplitude detector with a time constant chosen short enough to allow protective action to be taken after a quench begins but longer than several ac cycles. A threshold detector 212 is electrically connected to the amplitude detector 210 and is configured to provide an alarm if the input exceeds a particular programmed value. The alarm might be used, for example, to initiate a shutdown of the current in the coil.

FIG. 3 illustrates one embodiment of a superconducting coil 300 that includes both a superconducting tape 302 and a witness tape 304. The superconducting tape 302 may include a superconducting metal material. The metal material may include, for example, bismuth strontium calcium copper oxide, yttrium barium copper oxide, thallium barium calcium copper oxide, mercury barium calcium copper oxide and/or other suitable materials known in the art. The witness tape 304 may include a metal electrically connected to the superconducting tape. As illustrated in FIG. 3, the superconducting tape 302 and the witness tape 304 may be wound into a superconducting coil 300 formed in a flat pancake structure.

The superconducting metal material may be configured for high temperature superconducting. High temperature superconducting material may have a transition temperature greater than about 77° K. Some high temperature superconducting materials have transition temperatures between about 77° K and about 92° K. Some high temperature superconducting materials have transition temperatures between about 92° K and about 110° K. Some high temperature superconducting materials have transition temperatures between about 1 10° K and about 128° K. Some high temperature superconducting materials have transition temperatures between about 128° K and about 135° K. In some embodiments, high temperature superconducting material may have a transition temperature greater than about 135° K.

FIG. 4 illustrates a method for making a high temperature superconductor tape with a witness tape in a flat pancake structure 400. The method includes the steps of mixing high temperature superconductor materials to form a mixture 402; reacting the mixture of high temperature superconductor materials to form a powder 404; packing the powder into a plurality of billets 406; subjecting the plurality of billets to repeated drawing and swaging to produce a plurality of filaments 408; combining and deforming the plurality of filaments to form a high temperature superconducting tape 410; and winding the high temperature superconducting tape with a witness tape to form a high temperature superconductor coil in a flat pancake structure 414. Other types of methods for making superconducting coils and related systems and applications are described in Lubkin, Gloria B., Power Applications of High-Temperature Superconductors, Physics Today (March 1996) and Malozemoff, Alexis P. et al., High-Temperature Cuprate Superconductors Get to Work, Physics Today (April 2005), each of which is hereby incorporated by reference in its entirety.

It will be appreciated by those skilled in the art that various modifications and changes may be made without departing from the scope of the invention. Such modifications and changes are intended to fall within the scope of the embodiments, as defined by the appended claims. It will also be appreciated by those of skill in the art that parts included in one embodiment are interchangeable with other embodiments; one or more parts from a depicted embodiment can be included with other depicted embodiments in any combination. For example, any of the various components described herein and/or depicted in the figures may be combined, interchanged or excluded from other embodiments.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

What is claimed is:

1. A superconducting coil, comprising:
a superconducting tape comprising a superconducting metal material, the metal material selected from the group consisting of bismuth strontium calcium copper oxide, yttrium barium copper oxide, thallium barium calcium copper oxide and mercury barium calcium copper oxide; and
a witness tape comprising a metal electrically connected to the superconducting tape, wherein the superconducting tape and the witness tape are wound into a superconducting coil formed in a flat pancake structure.

2. A system for detecting quenches in superconducting coil, the system comprising:
a superconducting coil having a plurality of turns and comprising a plurality of wires, wherein the superconducting coil is wound into a pancake coil, and wherein the superconducting coil is configured to carry an alternating current;
a witness wire interwoven in the superconducting coil with the plurality of wires, wherein the witness wire comprises a tape; and
a quench detector electronically connected to the witness wire and to the superconducting coil at one end.

3. The system of claim 2, wherein the superconducting coil comprises an inductor.

4. The system of claim 2, wherein the superconducting coil comprises a winding in a transformer.

5. The system of claim 2, wherein the quench detector further comprises an isolation amplifier.

6. The system of claim 2, wherein the quench detector is configured to detect an increase in differential voltage.

7. The system of claim 6, wherein the quench detector is configured to detect the increase in differential voltage along the entire length of the superconducting coil.

8. The system of claim 2, wherein the plurality of wires comprise copper wires.

9. The system of claim 2, wherein the plurality of wires comprise brass wires.

10. The system of claim 2, wherein the plurality of wires comprise a material selected from the group consisting of bismuth strontium calcium copper oxide, yttrium barium copper oxide, thallium barium calcium copper oxide and mercury barium calcium copper oxide.

11. The system of claim 2, wherein the system is electrically connected to a power line transmission system.

12. The system of claim 2, wherein the witness wire comprises a feature to distinguish it from the plurality of wires.

13. The system of claim 12, wherein the feature is a color.

14. The system of claim 12, wherein the feature is a texture.

15. The system of claim 2, wherein the superconducting wire is configured for high temperature superconducting.

16. The system of claim 15, wherein the plurality of wires comprise a material with a transition temperature greater than about 77° K.

17. The system of claim 15, wherein the plurality of wires comprise a material with a transition temperature between about 77° K and about 92° K.

18. The system of claim 15, wherein the plurality of wires comprise a material with a transition temperature between about 92° K and about 110° K.

19. The system of claim 15, wherein the plurality of wires comprise a material with a transition temperature between about 110° K and about 128° K.

20. The system of claim 15, wherein the plurality of wires comprise a material with a transition temperature between about 128° K and about 135° K.

21. The system of claim 15, wherein the plurality of wires comprise a material with a transition temperature greater than about 135° K.

22. The system of claim 2, wherein the witness wire comprises a metal coated plastic film.

23. The system of claim 2, wherein the witness wire comprises part of an overall insulation between superconducting coil windings.

24. The system of claim 2, wherein the witness wire comprises one or more round wires in parallel.

25. The system of claim 2, wherein the witness wire comprises a resistance greater than 1000 ohms.

26. A method for making a high temperature superconductor tape with a witness tape in a flat pancake structure, the method comprising:
mixing high temperature superconductor materials to form a mixture;
reacting the mixture of high temperature superconductor materials to form a powder;
packing the powder into a plurality of billets;
subjecting the plurality of billets to repeated drawing and swaging to produce a plurality of filaments;
combining and deforming the plurality of filaments to form a high temperature superconducting tape; and
winding the high temperature superconducting tape with a witness tape to form a high temperature superconductor coil in a flat pancake structure.

27. The method of claim 26, wherein the high temperature superconductor materials comprise a material selected from the group consisting of bismuth strontium calcium copper oxide, yttrium barium copper oxide, thallium barium calcium copper oxide and mercury barium calcium copper oxide.

28. A utility system, comprising:
a utility configured to provide electric power to a load via a network;
a superconducting inductor immersed in a cryogenic fluid, wherein the superconducting transformer winding comprises a superconducting coil wound with a witness tape in a flat pancake structure, and wherein the transformer winding is configured to receive electric power from the utility; and
a quench detection and control circuit responsive to signals from the witness tape in the superconducting coil.
